(19) United States
(12) Patent Application Publication
(10) Pub. No.: US 2004/0070050 A1
(43) Pub. Date: Apr. 15, 2004

(54) Structures of vertical resistors and FETs as controlled by electrical field penetration and a band-gap voltage reference using vertical FETs operating in accumulation through the field penetration effect

(75) Inventor: Min Hwa Chi, Hsinchu (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/268,585

(22) Filed: Oct. 10, 2002

(51) Int. Cl. H01L 29/00

(52) U.S. Cl. 257/536

(57) ABSTRACT

A vertical resistor structure with a variable resistance is realized by biasing an adjacent control junction through a shallow trench isolation (STI) structure, thereby forming a depletion layer in the resistor region and varying its resistance. A vertical FET structure which is based on the foregoing vertical resistor structure, and which has a control junction isolated by a base region, can induce an accumulation or depletion layer for turn-on or turn-off operation. A band-gap voltage reference circuit is described using either two such vertical n-channel FET structures (in an n-well) with complimentary control junctions (a p+ junction and an n+/p-base junction) or two such vertical p-channel FET structures with complimentary control junctions (an n+ junction and a p+/n-base junction). The fabrication methods for vertical FETs are compatible with existing CMOS technology.

### BACKGROUND OF THE INVENTION

1. Field of the Invention

The invention relates to vertical semiconductor structures, and circuits and more particularly to structures relating to vertical variable resistors, vertical FETs and band-gap voltage references constructed from such vertical FETs, including process steps of fabricating same.

2. Description of the Related Art

The shallow-trench isolation (STI) is currently the most popular isolation scheme for advanced CMOS (e.g. 0.25 um and beyond) due to its superior capability for minimum isolation pitch, better planar surface, and enhanced latch-up immunity. However, as CMOS technology continuously advances to 0.13 um and beyond, the STI isolation spacing is small (e.g. ˜0.1 um, where u=10⁻⁶) enough for significant field penetration into the transistor channel (or body) area from adjacent poly gate as well as drain/source junctions. As a result of such electrical field penetration, there is a depletion region formed along the channel side-wall of the STI causing the transistor narrow width effect and transistor Vt fluctuations. Please refer to the following publications:

A. Bryant, W. Hänsch, and T. Mii, “Characteristics of CMOS Device Isolation for the ULSI Age”, International Electron Device Meetings, p.671, 1994.

C. Wang, P. Zhang, “Three-Dimensional DIBL for Shallow-Trench Isolation MOSFET's”, IEEE Trans. on Electron Device, V.46, No.1, p.139, 1999.

J. H. Sim, J. K. Lee, and K. Kim, “The Impact of Isolation Pitch Scaling on V_{TH} Fluctuation in DRAM Cell Transistors due to Neighboring Drain/Source Electric Field Penetration”, Symposium of VLSI technology, p.32-33, 1998.

In one way to eliminate such field penetration effect, a shielded STI was proposed by J. H. Sim, J. K. Lee, and K. Kim, in “High-performance cell transistor design using metallic shield embedded shallow trench isolation 9MSE-STI) for Gbit generation DRAM's”, IEEE Transaction on Electron Devices, Vol. 46, No. 6, p.1212-1217, 1999 by filling a layer of conducting material (e.g. doped poly) after liner oxidation of the isolation trench. The grounded conducting material in the trench can provide good shielding and therefore can eliminate the transistor narrow-width effect and Vt fluctuations.

As illustrated in FIG. 1 (not to scale), the n-channel body region 15a in p-substrate 12 will have a depletion layer 17 formed along the side-walls of STI 16 as a result of fringe field (as indicated by arrows A) from both poly-gate 19 and adjacent n+ junctions 18 or from adjacent poly gate (not shown), when biased high (e.g. +Vcc). The fringe field from the poly gate edge and n+ junctions (biased high) can expel holes and form depletion layers 17 along the side-wall of STI.

Similarly, a corresponding p-channel body region 15b in n-well 14 will also have a depletion layer 17 formed by the fringe field (as indicated by arrows A) from the edge of poly-gate 19 and adjacent p+ junctions 20 as shown in FIG. 2 (not to scale). Similarly, the fringe field from the poly gate edge and p+ junctions (biased low) can expel electrons and form depletion layers along the side-wall of STI. A few parameters of typical 0.13 um CMOS technology are listed here for references: STI depth ˜0.4 um, STI minimum width 0.1-0.15 um, n+ or p+ junction depth ˜0.8-0.12 um.

Such STI field penetration effect is considered undesirable in advanced CMOS (especially in DRAM, or SRAM arrays), a metallic-shielded STI was proposed by J. H. Sim, J. K. Lee, and K. Kim in “High-performance cell transistor design using metallic shield embedded shallow trench isolation (MSE-STI) for Gbit generation DRAM's”, IEEE Transaction on Electron Devices, Vol. 46, No. 6, p.1212-1217, 1999, by filling a layer of conducting material (e.g. doped poly) after liner oxidation of the trench. The grounded conducting material in the trench can provide a good shielding and therefore can eliminate Vt fluctuations by the field penetration effect.

The motivation for this invention, by contrast, is to maximize the field penetration effect through STI by modulating a vertical resistor by biasing adjacent junctions. This vertical (and variable) resistor, when operating to its maximum range as an open or a short, can also serve as a switch or vertical FET. A fabrication method to maximize the STI field penetration effect is also disclosed. Details are shown in later sections.

A well-known circuit configuration of a voltage reference is described by Gray and Meyer, “Analog VLSI Circuit Analysis”, chapter 12, Wiley, 1984, and is illustrated in FIG. 11 using 2 n-MOSFETs with different threshold voltages of Vt1 and Vt2, and which is referred to as a “V_{T}-difference” voltage reference circuit. The two n-MOSFETs with same size (i.e. same W/L) are biased by the same magnitude (typically 0.1 uA to 100 uA) current source I, and both n-MOSFETs are used as “pull-up” transistors. The threshold voltage Vₜ of the two transistors is made different by either channel implant or by a different doping type of the poly gate. The gate of the first n-MOSFET with Vt1 is grounded (as a convenient reference voltage). An operational amplifier (op-amp) OA is connected to the source sides A and B (for detecting the difference of Vₜ) and the op-amp output Vₒ is connected to the gate of the second n-MOSFET with Vt2 (for maintaining the second n-MOSFET turn-on). The output Vₒ from the op-amp is simply the Vₜ difference of the two n-MOSFET transistors, i.e. Vₜ₁−Vₜ₂. The accuracy of the circuits depends on the size matching of MOS transistors and the offset of the op-amp. The basic circuit configuration in FIG. 11 can be modified by various additional circuits for trimming or calibration purposes, and it is widely used in CMOS VLSI. The temperature coefficient of this circuit can be very good due to the cancellation of temperature dependence of n-MOSFET with different Vₜ. Correspondingly, a reference circuit using two p-MOSFETs can be similarly implemented.

Prior art U.S. patents which relate to the present invention are:

U.S. Pat. No. 6,078,094 (Poplevine et al.) shows a variable width vertical resist and STI process.

U.S. Pat. No. 6,051,474 (Beasom) teaches a method to bias the isolation trench fill.

U.S. Pat. No. 5,899,724 (Dobuzinsky et al.) describes a TIN vertical resistor. However, this reference differs from the invention.

U.S. Pat. No. 5,234,861 (Roisen et al.) discloses a method to form an isolation structure and to optionally bias it.

U.S. Pat. No. 4,933,739 (Harari) describes a vertical trench resistor.

The undesirable field penetration effect through STI in advanced CMOS can be utilized for a class of new vertical (variable) resistor and FET structures by biasing adjacent junctions for depletion layer or accumulation layer formation in the resistor region along the side-wall of an STI. This new family of devices (vertical resistor and FET) can be formed by CMOS compatible technology.

Also disclosed is a new voltage reference by utilizing such vertical FET with n+ and p+ control junctions. The difference of Fermi-levels of n+ and p+ doping (i.e. band-gap) in the control junction is used in the Vt-difference circuit configuration and the output is simply one silicon band-gap. Compared with conventional MOS transistor Vt-difference voltage reference, the proposed voltage reference has smaller layout (due to the vertical nature of FET) with less contact and connections, and smaller temperature coefficient.

### SUMMARY OF THE INVENTION

It is an object of at least one embodiment of the present invention to provide a vertical resistor structure with variable resistance and forming a depletion layer in the resistor region.

It is another object of the present invention to provide a vertical FET structure which has control junctions isolated by a base region and which can induce an accumulation and depletion layer for FET turn-on and turn-off operation.

It is yet another object of the present invention to provide fabrication methods for maximizing the STI field penetration effect and to provide fabrication methods compatible with CMOS technology regarding FET construction.

It is still another object of the present invention to provide a new band-gap voltage reference circuit using less real estate and requiring fewer contacts and connections.

It is a further object of the present invention is to implement the new band-gap voltage reference circuit with two n-channel or p-channel FETs with a complimentary control junction.

It is yet a further object of the present invention is to provide a new band-gap voltage reference circuit where the flat-band difference is one full silicon band gap.

It is still a further object of the present invention is to provide a new band-gap voltage reference circuit with a smaller temperature coefficient.

These and many other objects have been achieved by biasing adjacent control junctions through an STI and thereby forming a depletion layer in a channel region by varying its resistance. The new vertical FET structure has control regions (i.e., adjacent junctions) isolated by a base region with opposite doping type, depending on the bias applied to them, for turn-on or turn-off operation. The fabrication method for maximizing the STI field penetration includes deeper junctions, a shallow junction as resistor contact, a base implant for isolating the control junction from the substrate, and a separately optimized resistor region. Complimentary control junctions for n-channel FETs comprise the combination of a p+ junction and an n+/p-base junction and for p-channel FETs comprise the combination of an n+ junction and a p+/n-base junction. The vertical FETs are connected to current sources and an op-amp with the circuit configuration of Vt-difference reference. The output voltage is the difference of Vt (accumulation) of vertical FETs, which is their difference in V_{fb}. The savings in real estate are due to the vertical nature of the FETs which makes for a more compact design. The fabrication methods for vertical FETs, which are all compatible with CMOS technology, require additional process steps for the deeper trench (by masking and trench etch), deeper junctions (by masking and implant with higher energy), and doping optimization in the vertical FET area (by masking and implant) for enhancing the field penetration (or coupling) from the “control junction” through the STI oxide.

These and many other objects and advantages of the present invention will be readily apparent to one skilled in the art to which the invention pertains from a perusal of the claims, the appended drawings, and the following detailed description of the preferred embodiments.

In the following, first and second conductivity types are opposite conductivity types, such as N and P types. Each embodiment includes its complement as well. Note also that the figures herein illustrate vertical cross sections of devices and that the devices extend laterally (into and/or out of the page) in a manner appreciated by those skilled in the art.

### BRIEF DESCRIPTION OF THE DRAWINGS

FIG. 1 is a sketch of cross-section of n-channel body region and adjacent n+ junctions (not to scale) of the prior art.

FIG. 2 is a sketch of cross-section of p-channel body region (in n-well) and adjacent p+ junctions (not to scale) of the prior art.

FIGS. 3a and b are cross-sections of proposed vertical resistor (p-type and n-type) structure (not to scale) of the present invention.

FIG. 4 is a sketch of vertical p-type silicon with enhanced field penetration with deeper trench and junctions and separately implanted resistor region for optimum doping level.

FIG. 5 is a block diagram of the present invention of the process flow for fabrication of vertical resistors with extra masking steps for forming deeper junctions and a trench and separately optimized doping level at resistor area.

FIGS. 6a and 6b are a simple model with notations for illustration of the doping effect on the vertical resistor.

FIG. 7 is a graph of the calculated design curve of the resistor ratio (Rmax/Rmin) vs. doping level.

FIG. 8a shows in a sketch how the p-type resistor with the “control junction” as p+ in n-base can serve as a switch or FET. The p+ junction in n-base is biased to +Vcc for inducing a depletion layer for turn-off.

FIG. 8b is like FIG. 8a except that the p+ junction in n-base is biased to −Vcc for inducing a (hole) accumulation layer for turn-on.

FIG. 9a shows in a sketch how the n-type resistor with the “control junction” as n+ in p-base can serve as a switch or FET. The n+ junction in p-base is biased to −Vcc for inducing a depletion layer for turn-off.

FIG. 9b is like FIG. 9a except that the n+ junction in p-base is biased to +Vcc for inducing an (electron) accumulation layer for turn-off.

FIGS. 10a and 10b illustrate a general cross-section of a new band-gap voltage reference circuit with two vertical p-FETs and the associated I-V curves, respectively.

FIG. 11 is a sketch of a basic voltage reference circuit configuration with n-MOS as pull-up transistors of the prior art.

FIG. 12a illustrates a preferred embodiment of the present invention of a new band-gap voltage reference circuit by using two n-channel vertical FETs (in an n-well) with “complementary” control junctions.

FIG. 12b is the equivalent circuit of FIG. 12a.

FIG. 13a illustrates a preferred embodiment of the present invention of a new band-gap voltage reference circuit by using two p-channel vertical FETs (in a p-substrate) with “complementary” control junctions.

FIG. 13b is the equivalent circuit of FIG. 13a.

FIG. 14a illustrates that the band-gap reference can also be formed by utilizing two vertical n-FETs in the saturation region.

FIG. 14b is the equivalent circuit of FIG. 14a.

FIG. 15a illustrates that the band-gap reference can also be formed by utilizing two vertical p-FETs in the saturation region.

FIG. 15b is the equivalent circuit of FIG. 15a.

In the figures like parts are identified by like numerals.

### DESCRIPTION OF THE PREFERRED EMBODIMENT

### Vertical Resistor (#1) Structure Using a Typical CMOS Process

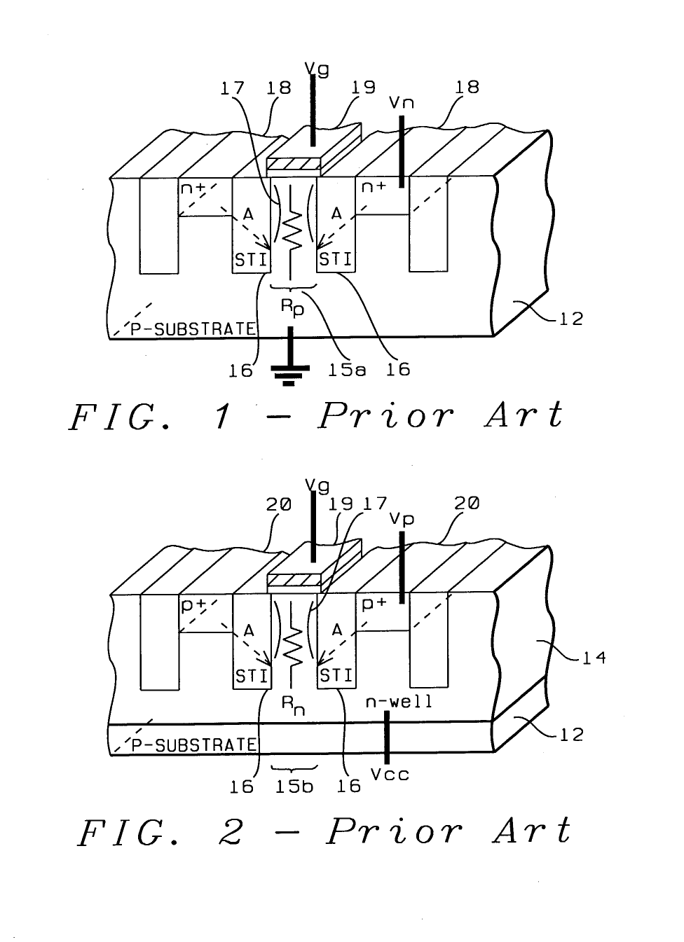

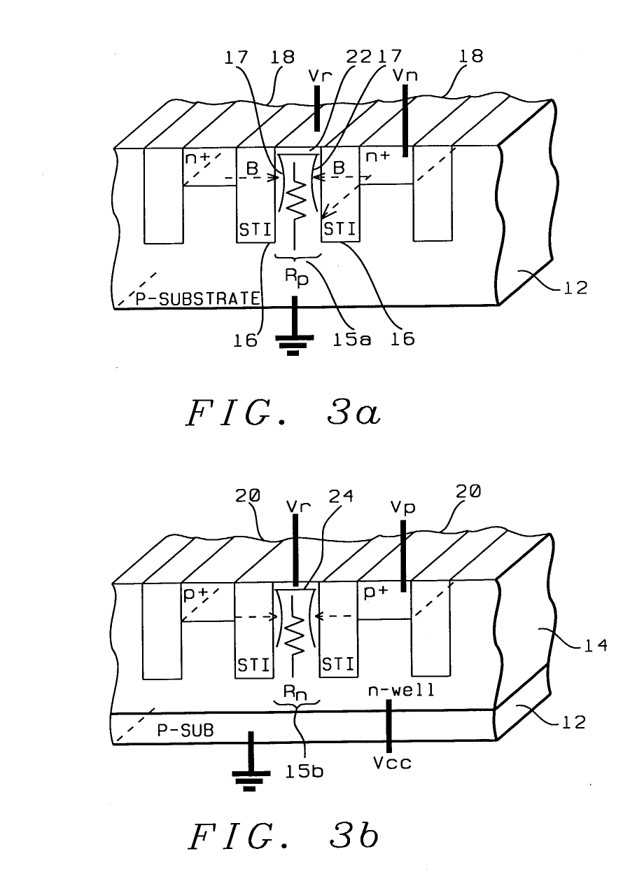

Described next is a vertical variable resistor controlled by the field penetration effect from adjacent junctions through the STI structure. The “channel region” in FIG. 1 and FIG. 2 of the prior art has a parasitic resistance, which is also modulated by the depletion layer along side-wall of STI. The proposed structure, as shown in FIGS. 3a, 3b and described in detail below, is developed from the “channel region” in FIG. 1 and FIG. 2 but with three modifications: i.e., no poly-gate on top, no Vt (or anti-punch-through) implants into the resistor region, and only lightly doped drain junctions for resistor contact as formed by the ldd implant steps in typical CMOS technology, e.g. nldd implant for n-MOS and n-type resistor, pldd implant for p-MOS and p-type resistor. The ldd junctions are shallower than source/drain junctions and range from 20 to 100 nm (nm=10⁻⁹ meter), but preferably range from 20 to 80 nm, so that the field penetration from adjacent junctions can be stronger for forming depletion layers along STI side-wall. The doping of the resistor region is desirably lower, ranging from 1×10¹⁴ to 1×10¹⁶ cm⁻³, so that the depletion layer can be thicker in order for larger range of resistance variations (more discussions on resistor operation later). The adjacent junction simply serves as “control junction” for modulating the vertical resistance by applying biases (i.e. 0 v to Vcc). The usual Co-silicided junctions are not shown in FIGS. 3a, b for simplicity. The fabrication of such vertical resistor can be readily implemented (i.e., “it is free”) via the typical CMOS technology with proper layout modifications, e.g. blocking n+ or p+ implants to resistor area, blocking Vt or anti-punch-through implants to the resistor area, opening nldd or pldd implants to n or p resistor area, etc.

FIG. 3a is a cross-section of the proposed vertical p-type resistor structure (not to scale). FIG. 3a shows a p-channel region 15a (the channel region or resistor area) in p-substrate 12. Located on either side is an STI 16 and to either side of the STI are adjacent n+ junctions (control junctions) 18. Pldd junction 22 is formed by pldd implant on top of p-channel region 15a flush with the top of p-substrate 12. Field penetration from the adjacent n+ junctions, indicated by arrows B, when biased high (e.g. +Vcc) expels holes and forms a depletion layer 17 along the side-walls of STI 16. Pldd and nldd control junctions have a depth ranging from 0.1 to 0.5 um (um=10⁻⁶ meter), but their depth cannot exceed the depth of the STI structures. The STI structures have a typical depth ranging from 0.3 to 0.5 um.

FIG. 3b is a cross-section of the proposed vertical n-type resistor structure (not to scale). The structure is similar to FIG. 3a except that the entire structure is deposited in n-well 14, the adjacent junctions 20 are p+ junctions, the channel region is a p-channel region 15b and that the contact for the channel region is an nldd junction 24 formed by an nldd implant. In addition, the n-well is deposited on p-substrate 12.

### Vertical Resistor Structure (#2) with Enhanced Field Penetration Effect on CMOS

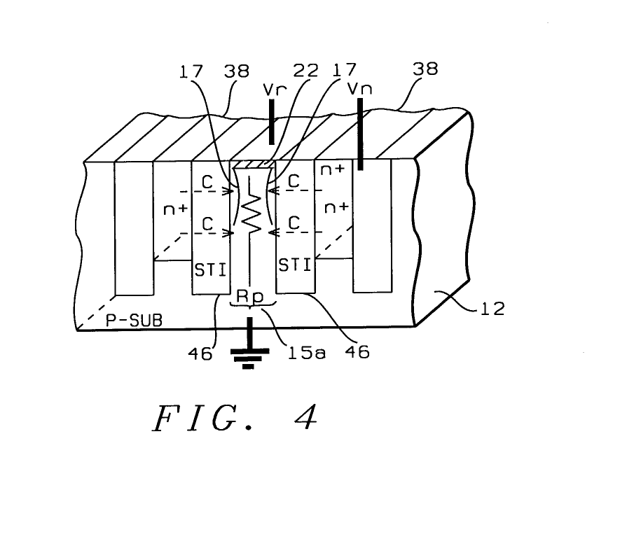

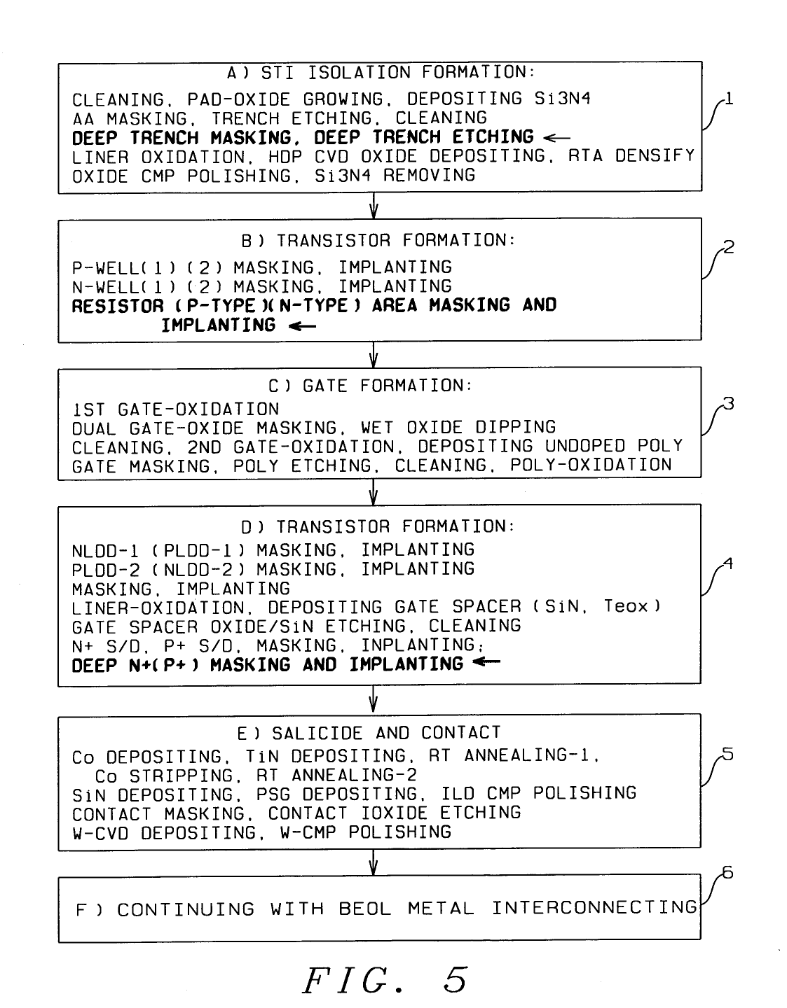

Referring now to FIG. 4, the STI field penetration effect can be further enlarged by implementing a few extra process steps as follows and as illustrated in the cross-sectional view of FIG. 4 and when compared with the standard CMOS design of FIG. 3a and FIG. 3b. Firstly, the adjacent junctions 38 can be deeper (but slightly less than the depth of STI 46) by applying extra masking and implant step. Secondly, the doping of the resistor region 15a can be separately implanted for optimizing its dopant concentration. Thirdly, the adjacent junctions 38 can be either located on one side, or surrounding the resistor region. Fourthly, the trench 46 can also be deeper (than the usual CMOS STI) by applying extra masking and etching steps. The depth of STI trench 46 in this case ranges from 0.3 to about 2.0 um but, of course, cannot exceed the n-well or deep n-well depth. The typical n-well depth ranges from 1 to 2 um, and the typical deep n-well depth ranges from 2 to 4 um in 0.25 CMOS technology. Arrows C illustrate the increased field penetration which implies an increase in the thickness of the depletion layer 17.

The fabrication method is illustrated in FIG. 5 and listed in greater detail below with extra steps (identified by arrows) compatible with CMOS technology. The fabrication comprises steps a-f below with additional steps for a-e:

Block 1 Describes

a) STI isolation formation:

Cleaning, pad-oxide growing, depositing Si3N4;

AA masking, trench etching, cleaning;

Deep trench masking, deep trench etching;←

Liner oxidation, HDP CVD oxide depositing, RTA densify;

Oxide CM polishing, Si3N4 removing;

Block 2 Describes

b) Transistor formation:

p-well (1) masking, implanting;

p-well (2) masking, implanting;

n-well (1) masking, implanting;

n-well (2) masking, implanting;

resistor (p-type) area masking and implanting;←

resistor (n-type) area masking and implanting;←

Block 3 Describes

c) Gate formation:

1st gate-oxidation;

Dual gate-oxide masking, wet oxide dipping;

Cleaning, 2nd gate-oxidation, depositing undoped Poly;

gate masking, poly etching, cleaning, poly-oxidation;

Block 4 Describes

d) Transistor formation:

nldd-1 masking, implanting;

pldd-1 masking, implanting;

pldd-2 masking, implanting;

nldd-2 masking, implanting;

Liner-oxidation, depositing gate spacer (SiN, Teox);

Gate spacer oxide/SiN etching, cleaning;

n+ S/D masking, implanting;

p+ S/D masking, implanting;

deep n+ masking and implanting; (optional with additional p-base implant)←

deep p+ masking and implanting; (optional with additional n-base implant)←

Block 5 Describes

e) Salicide and contact:

Co depositing, TiN depositing, RT Annealing-1, Co stripping, RT Annealing-2;

SiN depositing, PSG depositing, ILD CMP polishing;

Contact masking, contact oxide etching;

W-CVD depositing, W-CMP polishing;

Block 6 Lists the Final Step

f) Continuing with BEOL metal interconnecting.

The optional n-base and p-base implants will be described later.

### Analysis of Depletion Layer and Resistance Variation

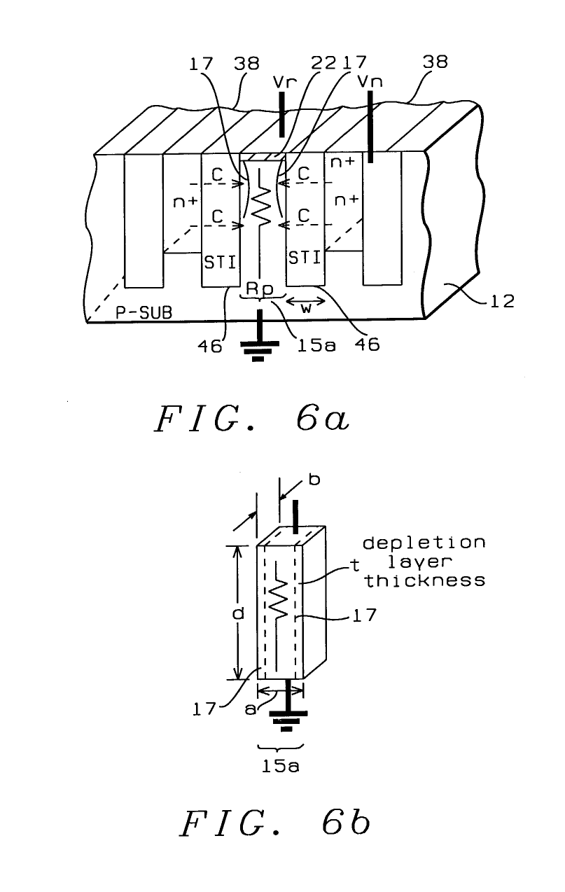

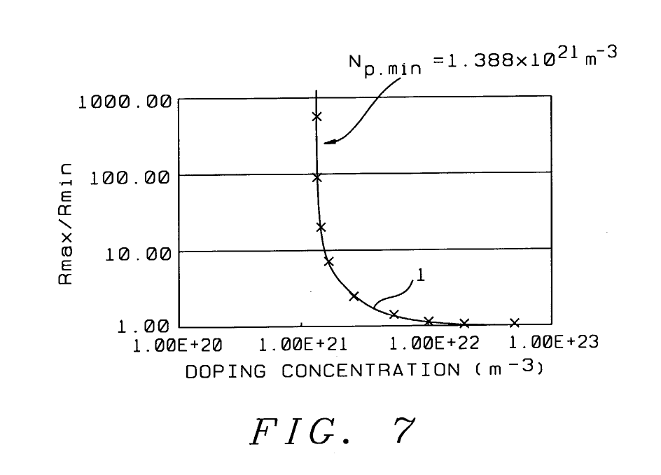

FIGS. 6a and 6b are a simple model of a vertical resistor with notations for illustrating the doping effect on a vertical resistor 15a, where ab represents the resistor cross-section area, a is the minimum active area (OD) width, b is the dimension for the depth of resistor, t is the depletion layer thickness, d is the STI depth, w is the STI spacing (or width of the oxide inside the shallow trench 46). FIG. 6a is a copy of FIG. 4 using the same numerals for the same components.

Now referring to FIG. 6, a simple model for the vertical resistor is shown with 2-side depletion layers 17 (i.e., the effective conducting cross-section area of the resistor becomes: (a−2t)·b) by assuming uniform doping in the resistor region and vertical trench profile. The electrical field (on the silicon surface along the STI side-wall) from the n+ “control” junction can be estimated by using simple 1D analysis:

Eₛᵢ=∈ₒₓ(Vₙ−V_{fb})/(∈ₛᵢw) (1)

Where w denotes the STI spacing (or STI oxide thickness viewed from side-wall of vertical silicon region). Vₙ is the n+ junction bias (e.g. 0 v to V_{cc}, with V_{cc} of 3.3 v or 2.5 v typically used on 0.35 μm or 0.25 μm CMOS chip, respectively). The flat-band voltage (V_{fb}) of the silicon surface along STI side-wall is about −0.6 v (i.e. mainly the differences of the electron Fermi level differences between the n+ junction and p-silicon region). The relative dielectric constants are ∈ₛᵢ(˜11.9) and ∈ₒₓ(˜3.9) Notice that even if Vₙ is biased to 0 v, there is already a field on the silicon surface along side-wall for depleting holes and forming depletion region (due to the built-in field established by the Fermi level difference). Additional Vₙ will further increase the surface field and increase the thickness of depletion layer. The depletion layer thickness (t) along STI side-wall is then easily estimated by:

t=(∈ₛᵢEₛᵢ)/(q·Nₚ)=εₒₓ(Vₙ−V_{fb})/(w·q·Nₚ) (2)

where, Nₚ is the p-type doping concentration; q is the electron charge 1.602×10⁻¹⁹ coulomb. The above expression relates the depletion layer thickness to STI width, n+ junction bias, and p-substrate doping. The resistivity (p)of the p-type resistor region is simply:

ρ=(Nₚ·g·μₕ)⁻¹ (3)

The resistance of the vertical resistor is then related to the effective area (a−2t).b of cross-section and length (d) (or the depth of trench) of the resistor:

R=ρ·d/(b·(a−2·t)) (4)

Where a is the minimum width of active area, and is becoming narrower by the depletion layer. The minimum resistance (Rₘᵢₙ) occurs with Vn biased to 0 v (i.e. smallest depletion layer), and the maximum resistance (Rₘₐₓ) occurs with Vₙ biased at +V_{cc}. The ratio of Rₘₐₓ/Rₘᵢₙ is of interest as follows:

Rₘₐₓ/Rₘᵢₙ=(a−2tₘᵢₙ)/(a−2tₘₐₓ) (5)

The critical doping level below which the entire silicon region is depleted can be estimated by setting (a=2tₘₐₓ) and using eq. (2).

N_{p,min}=2·∈ₒₓ(Vₙ−V_{fb})/(a·w·q) (6)

### Design of Vertical Resistor for Analog Applications

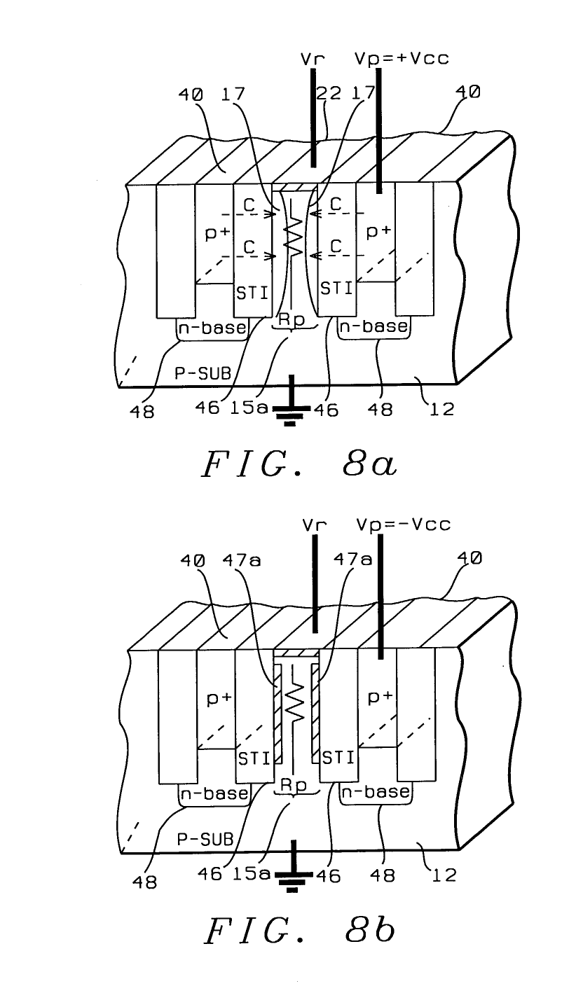

The design of a variable resistor is discussed briefly for reference. FIG. 7 shows a calculated design curve 1 of the resistance ratio (Rₘₐₓ/Rₘᵢₙ) vs. p-type doping level based on a minimum active width (OD) of a=0.1 um (u=10⁻⁶), an STI spacing of w=0.1 um, a flat band voltage Vfb of −0.6 v, and Vcc of 2.5 v. The resistor ratio increases rapidly when the doping level decreases below a critical value when the resistor region is fully depleted. In this example in FIG. 7, this critical value of minimum doping concentration of N_{p.min} is ˜1.338×10²¹m⁻³ for a completely depleted resistor. This shows that the doping level of the resistor region is an important process parameter for adjustment to the desirable range of the resistance variation. FIG. 7 also shows that when the doping level is high, then the resistance ratio approaches 1. For advanced CMOS (e.g. 0.18 um and beyond), the channel region has higher doping level for Vt adjustment; therefore the vertical resistor region will be blocked against Vt implant and its doping level is adjusted by using a separate implant for optimized doping level. After the desirable resistance ratio is determined, the Rₘᵢₙ can be designed by adjusting the total cross-section area of the vertical resistor by using geometry of serpentine or inter-digital stripes with long edges but minimum active area width.

### Vertical Resistor Structure (#3) Used as Vertical FET

The above described variable resistor may be utilized as a switch or FET if the silicon surface along STI side-wall can be accumulated by the bias from adjacent “control junction” 40 as shown in FIGS. 8a, 8b using a p-type resistor for illustration. The structure of the “control junction 40” is p+ in n-base 48, so that the p+ junction can be biased to either −Vcc (FIG. 8b) or +Vcc (FIG. 8a) for inducing a (hole) accumulation 47a or depletion layer 17 on the side-wall of STI 46, respectively. The n-base can be formed at the same time as the deep p+ junction by implants sequentially (e.g., implanting Phosphorus first, then implanting Arsenic). The n-base is left floating and serves as electrical isolation between the p+ “control junction” and the p-substrate 12 below. The accumulation layer 47a provides a conducting channel and therefore results in a low “on” resistance. The depletion layer is designed to be fully depleting the silicon area when p+ control junction is biased to +Vcc, for a large “off” resistance. Note that the −Vcc can be generated on-chip by well-known charge-pump techniques.

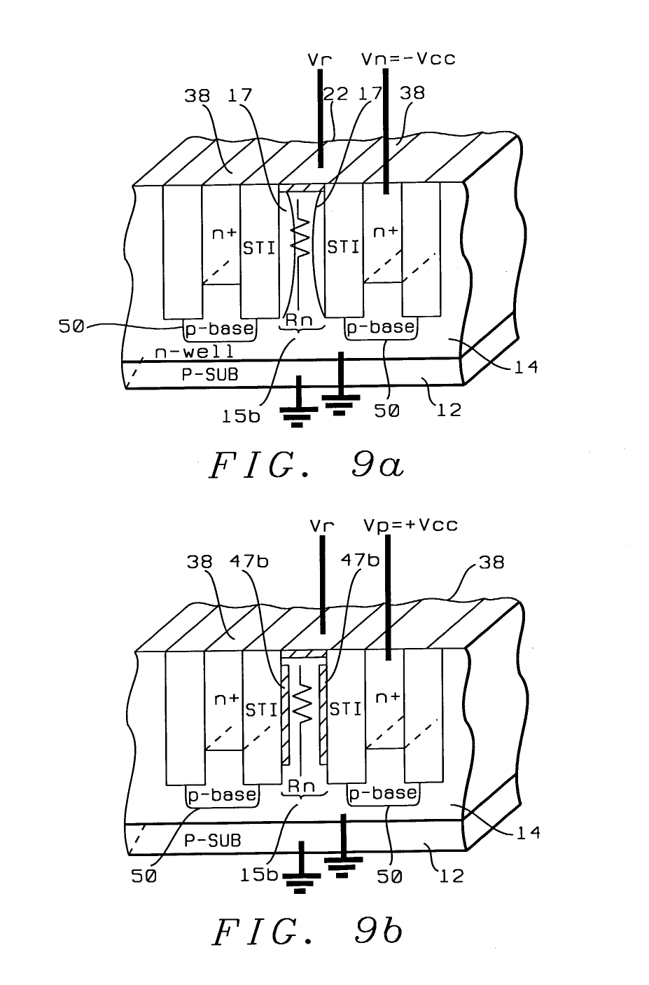

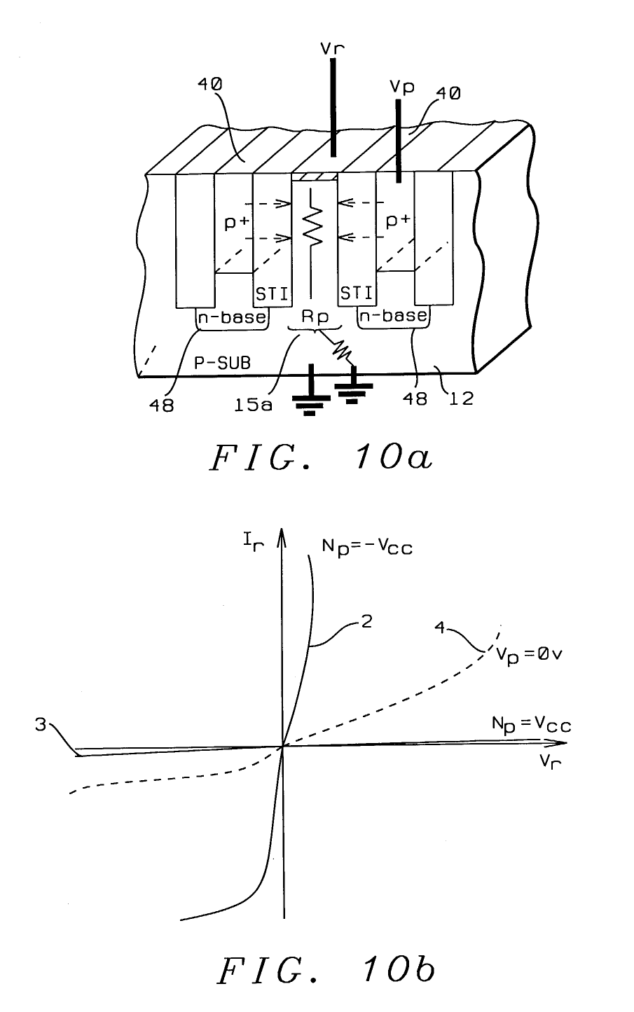

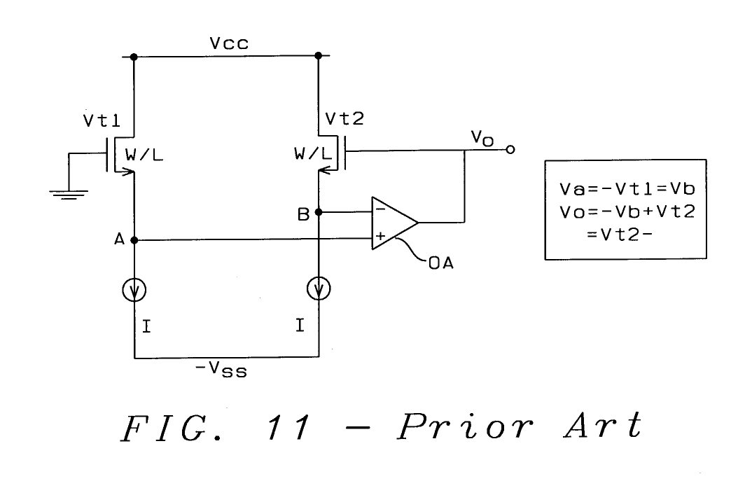

This type of vertical resistor, which serves as a switch or FET as controlled by the adjacent junction bias, utilizes the accumulation layer for “turn-on” and the depletion layer for “turn-off”. This type of FET with turn-on by accumulation and turn-off by bulk depletion is a unique feature for such vertical switch or FETs. A corresponding structure of a vertical switch or FET, based on n-type resistor, can be similarly formed with n+ junction in p-base as “control junction” as shown in FIGS. 9a, 9b. Still referring to FIGS. 9a, 9b, the n-type resistor 15b with the “control junction 38” as n+ in p-base 50 can serve as a switch or FET. The n+ junction 38 in p-base can be biased to +Vcc (FIG. 9b) and −Vcc (FIG. 9a) for inducing an (electron) accumulation layer 47b for turn on and a depletion layer 17 for turn-off, respectively, with p-substrate 12 and n-well 14 biased to typically ground (as a reference). Note that if the n-well is biased to Vcc, then n+ junction 38 needs to be biased to 2Vcc and 0 v for turn-on and turn-off, respectively. Note that a voltage bias higher than the externally supplied Vcc can be generated on-chip by well known charge-pump techniques.

### I-V Characteristics of a Vertical FET

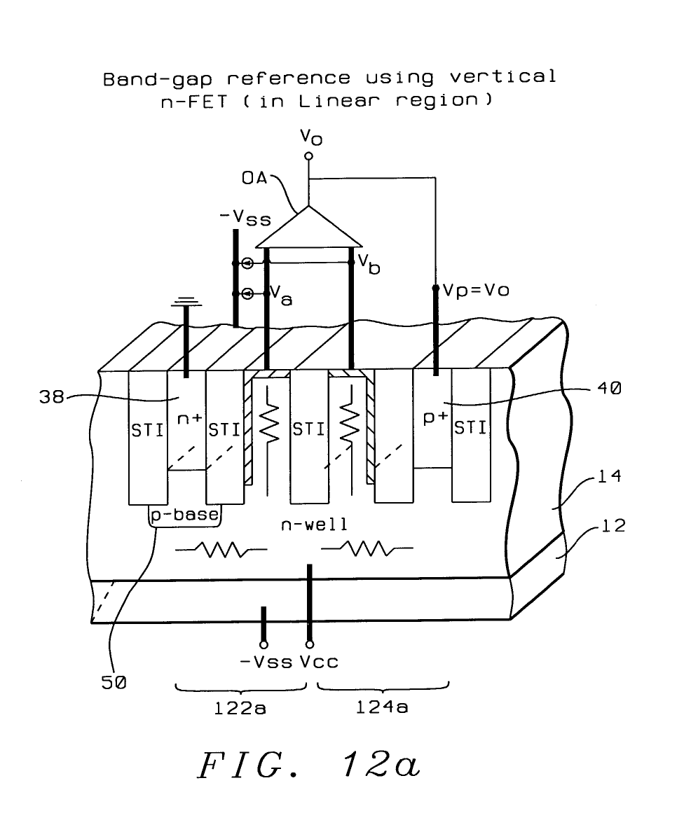

The I-V curve across a vertical p-FET of FIG. 10a is further illustrated in FIG. 10b. When biasing the control-junction (p+/n-base) 40, 48 to −V_{cc}, see Curve 2, the surface of the p-channel 15a is in strong accumulation and a large current (Iᵣ) flows through the vertical FET (i.e. on-state) with Vᵣ biased to either positive or negative directions. When biasing the control junction to +V_{cc}, see Curve 3, the p-channel is fully depleted and there is a small (leakage) current flowing through the device (i.e. off-state) with either positive or negative Vᵣ. When the control junction is grounded (i.e. Vₚ=0 v), see Curve 4, the surface is slightly accumulated (due to the Fermi level difference of p+ doping and the p-type doping in channel), and the current (Iᵣ) has a “linear region” at smaller values of Vᵣ. As the voltage across the FET (i.e. Vᵣ) increases toward more positive, Iᵣ increases faster due to heavier accumulation layer induced by the voltage drop across the p-channel and p-substrate 12. Viewed another way, the small-signal resistance (measured from the inverse of the I-V slope) decreases with more positive Vᵣ due to stronger accumulation. As Vᵣ increases in magnitude toward more negative, however, the current Iᵣ increases more slowly or even close to flat (i.e., in “saturation region”) due to growing depletion layer induced by the voltage drop across the p-channel and p-substrate. Note that the vertical n-FET will have similar I-V characteristics corresponding to the vertical p-FET, but with reversed polarity of bias.

### Dual STI Scheme for Further Enhancement of Field Penetration Effect

For further enhancing the field penetration effect, the trench for resistor area may be filled by high dielectric materials (e.g. Ta2O5, Al203, or silicon nitride, etc.) instead of silicon oxide by various CVD methods. Certainly, the trench for CMOS area should be filled with lower dielectric constant material (e.g. CVD oxide or FSG, etc.). Therefore, this leads to a need of dual trench scheme, i.e. one deeper trench with high-k material filling (for enhancement of field penetration) on vertical resistor area, and shallower trench with low-k material filling (for isolation) on CMOS areas.

### Band-Gap Reference Using Vertical n-FET (in Linear Region)

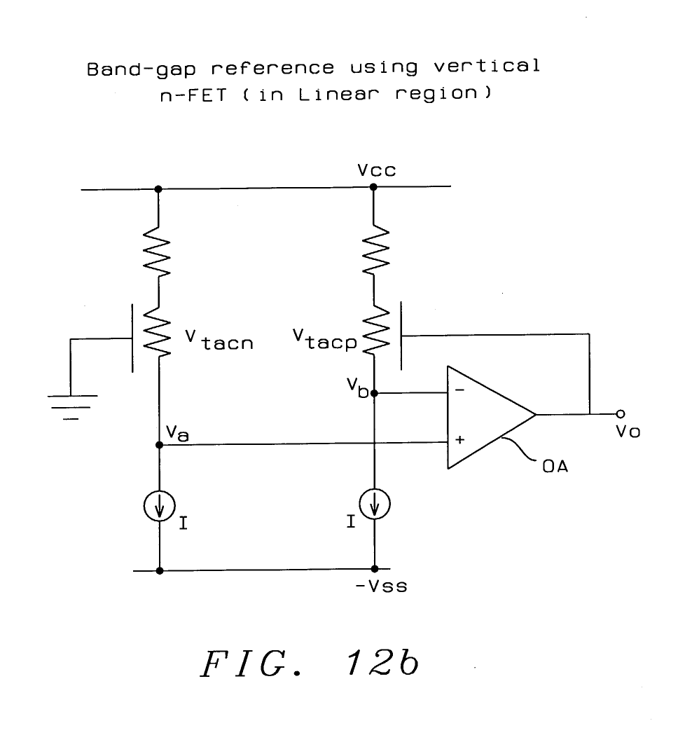

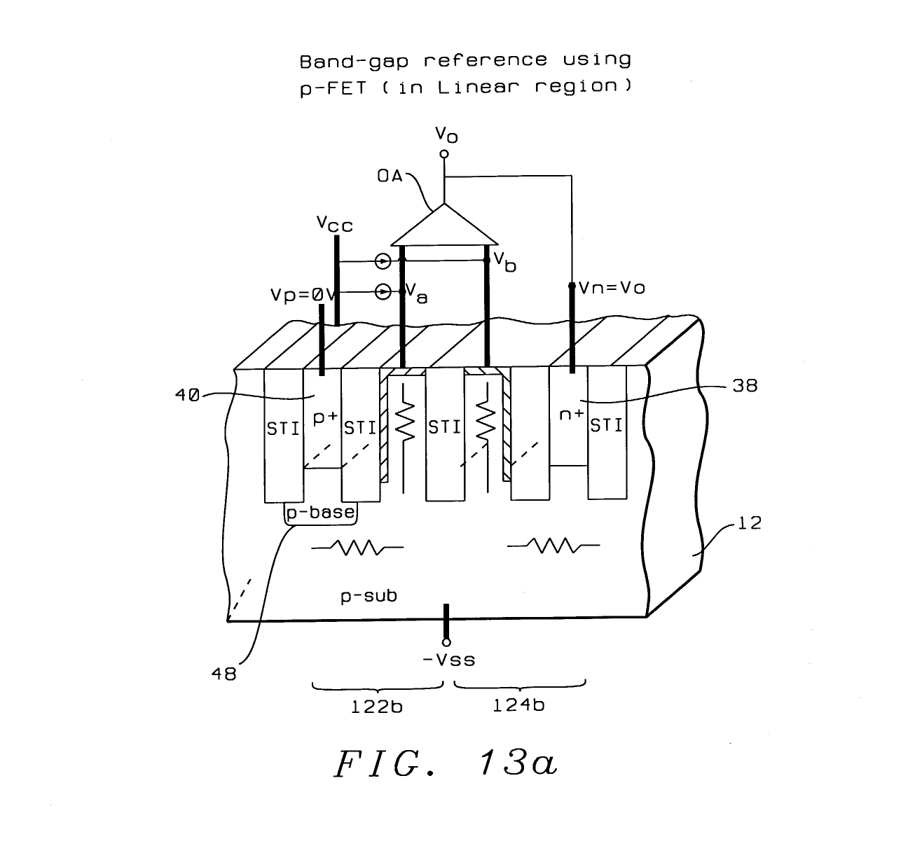

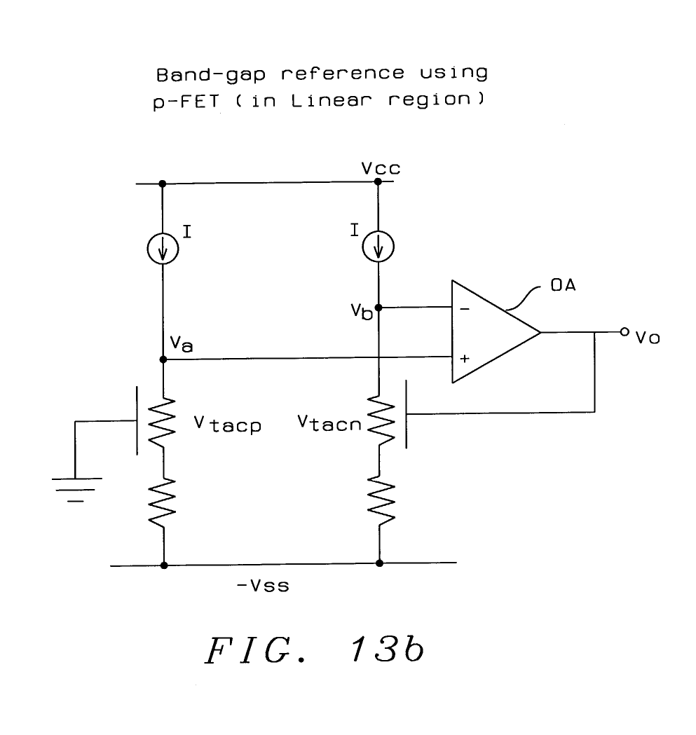

The new band-gap voltage reference circuit is based on two vertical n-FETs with n-type and p-type control junctions respectively. The difference in the “threshold voltage” for forming an accumulation layer along the vertical side-wall provides a reference voltage close to the silicon band-gap through the Vₜ-difference reference circuit. FIGS. 12a, 12b illustrate such voltage reference circuit by using two vertical n-FETs 122a, 124a (as “pull-up” transistor) with “complementary” control junctions (i.e. one a p+ junction 40 and another an n+/p-base junction 38, 50,). The vertical n-FETs are connected to current sources I (e.g. in the range of 0.1 uA to 100 uA) and op-amp OA as shown in FIG. 12a and its equivalent circuit in FIG. 12b (note. same circuit configuration as in FIG. 11). The output voltage is simply the difference of Vt (defined here as the threshold voltage of the control junction for inducing accumulation layer, see the next section for a further detailed definition) of the vertical FETs. Note that both vertical n-FETs are operating in the “linear region” (i.e., no need of strong turn-on, and thus saving the need of additional charge pumps on chip). P-substrate 12 is tied to −Vss and N-well 14 is tied to Vcc.

The threshold voltage for forming an accumulation layer (referred to as V_{tac}) on a side-wall may be defined as: V_{tac}=V_{fb}+2Φₙ, where Φₙ is the bulk Fermi level of the n-channel area. Note that Φₙ=(kT/q).ln(N_{d}/nᵢ),where k is the Boltzmann constant, T the absolute temperature, q the electron charge, N_{d} the doping of n-channel area, and nᵢ is the intrinsic carrier concentration of Silicon. V_{fb} is the flat band voltage viewed from the control junction. It is easily seen that the difference of Vₜ of accumulation viewed from the p+ control junction and n+ control junction is simply the difference of their flat-band voltage V_{fb}, i.e. V_{tacp}−V_{tacn}=V_{fbp}−V_{fbn}, which is in turn simply one band-gap E_{g}. Due to the heavy doping of p+ and n+ on the control gate, the V_{fbp} is more positive than V_{fbn} by one full band-gap (E_{g}˜1.2 v). Note that if the connection of the two vertical n-FETs to the op-amp inputs is swapped (or equivalently, the polarity of control junctions is swapped), then the output will be reversed to −1.2 v.

### Band-Gap Reference Using p-FET (in Linear Region)

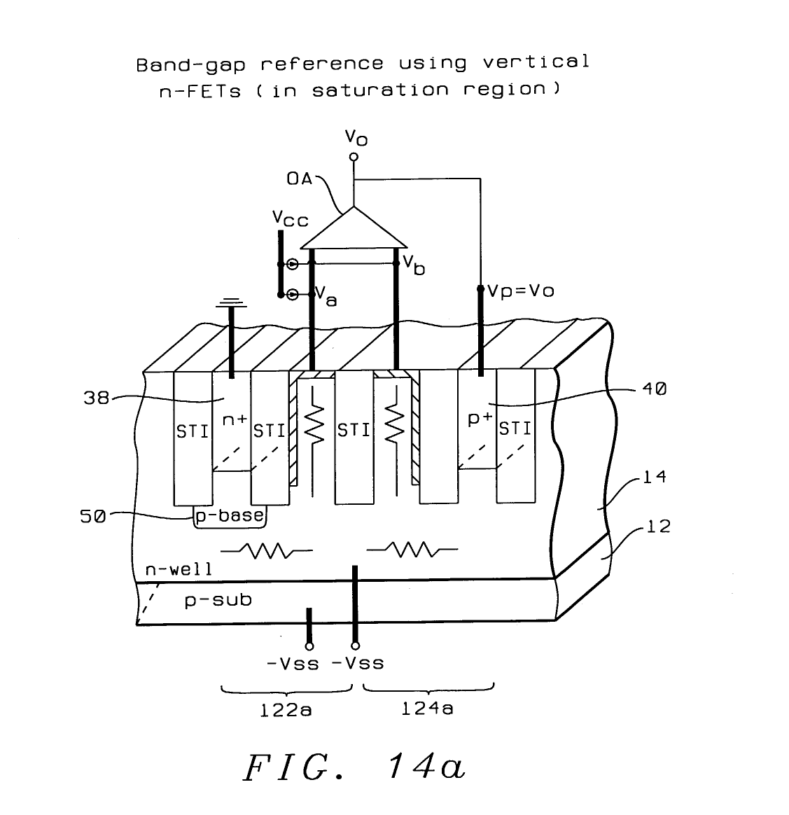

Similarly, two p-channel vertical FETs can also be used to form a “band-gap” reference circuit as shown in FIG. 13a and its equivalent circuit in FIG. 13b. Both vertical p-FETs 122b, 124b are used as “pull-down” transistors. Similarly, if the connection of two p-FETs to the op-amp inputs is swapped, then the output will be reversed to +1.2 v. The two p-channel vertical FETs are in p-substrate 12 and have “complementary” control junctions (i.e. one is n+ junction 38, and the other is p+/n-base junction 40, 48). The vertical FETs are connected to current sources I and op-amp OA in FIG. 13a and its equivalent circuit in FIG. 13b. The output voltage Vo is simply the flat-band difference from the n+ and p+ junction and is close to one silicon band-gap (˜1.2V).

### Band-Gap Reference Using Vertical n-FETs (in Saturation Region)

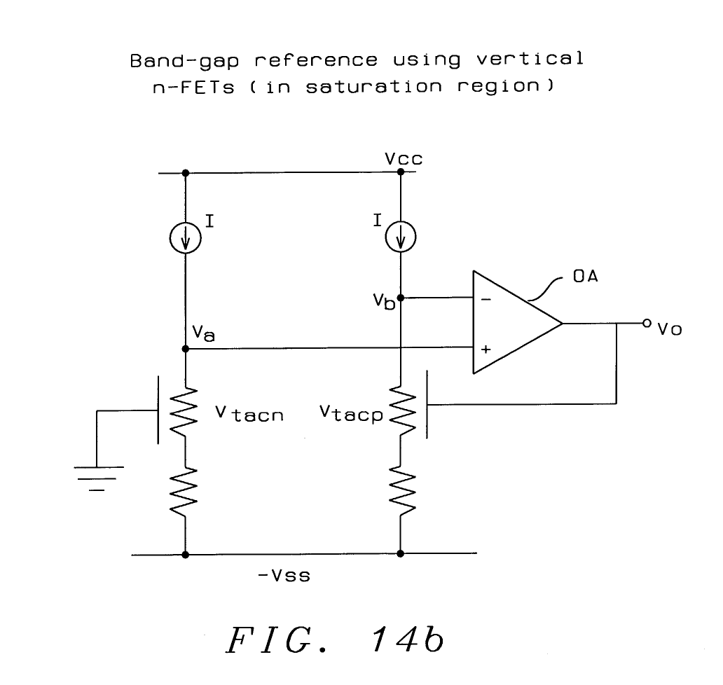

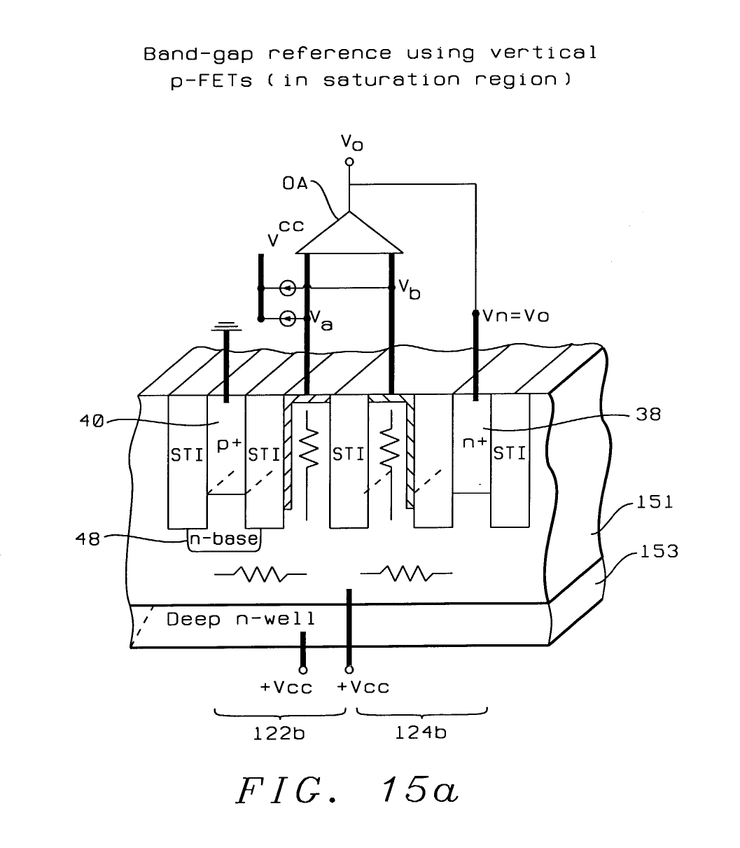

The band-gap reference can also be formed by using two vertical n-FETs 122a, 124a operating in saturation as shown in FIG. 14a and its equivalent circuit in FIG. 14b. Note that the n-well 14 is shorted to p-substrate 12 and biased to −Vₛₛ. Both vertical n-FETs 122a, 124a are used as pull-down devices (as similar to FIG. 13) but with “complementary” control junctions (i.e. one a p+ junction 40 and an n+/p-base junction 38, 50, similar to FIG. 12. Again, when reversing the connections to op-amp OA, a negative E_{g} will result.

### Band-Gap Reference Using Vertical p-FETs (in Saturation Region)

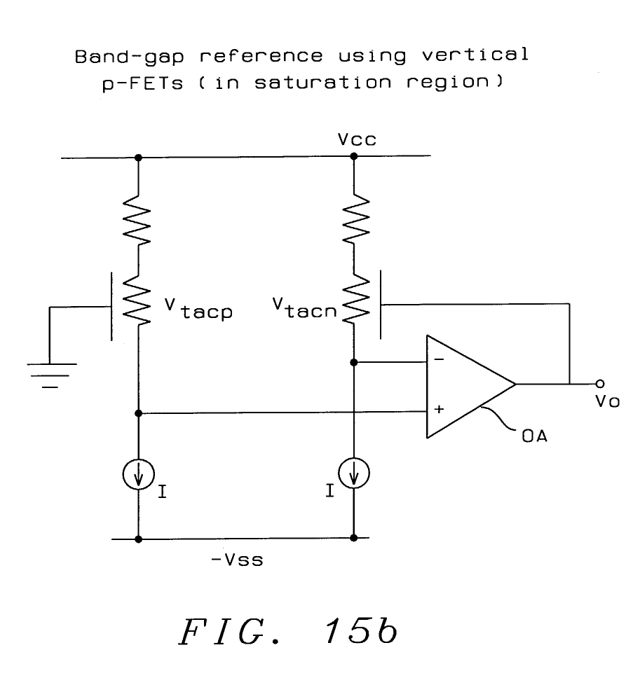

The band-gap reference can also be formed by using two vertical p-FET operating in saturation as shown in FIG. 15a and its equivalent circuit in FIG. 15b. Note that the p-well 151 is fabricated inside deep n-well 153 and that both are shorted to +V_{cc}. Both vertical p-FETs 122b, 124b are used as pull-up device (similar to FIG. 12) but with “complementary” control junctions (i.e. one is n+ junction 38, and the other is p+/n-base junction 40, 48, similar to FIG. 14). Again, when reversing the connection to op-amp OA, a reversed Vₒ will result.

Fabrication of vertical FETs: For enhancing the field penetration (or coupling) from the “control junction”, there are additional process steps for deeper trenches (by masking and trench etch), deeper junctions (by masking and implant with higher energy), and doping optimization in the vertical FET area (by masking and implant).

Dual STI scheme: Further, the trench filling for vertical FET area may be filled by high dielectric (i.e., high-k) materials (e.g. Tab 2O5, Al203, or silicon nitride, etc.) for more enhanced field coupling from adjacent junctions. Certainly, the trenches for the CMOS area is filled by a lower dielectric constant (low-k) material (e.g. CVD oxide or FSG, etc.) for better isolation. Therefore, this leads to a need of dual trench schemes, i.e., one deeper trench with high-k material filling (for enhancement of field penetration) on vertical FET areas, and shallower trench with low-k material filling (for isolation) on CMOS areas.

### Advantages

Advantages of vertical resistor and FET: The fabrication methods are fully compatible with advanced CMOS technology with mainly implant and masking steps. With continuously scaling for future 0.1 um and beyond, the effect of fringe field will be increasingly pronounced, therefore, the disclosed devices will be promising as new device concepts especially for future generations of CMOS technology.

Vertical FET based band-gap reference: There are two advantages of this disclosure when compared to conventional MOS transistor based voltage references. Firstly, the proposed reference circuit has a smaller layout due to the vertical nature of the FET with fewer contacts and connections. Secondly, the temperature coefficient is smaller, when compared to conventional Vₜ-difference voltage references, because the output is the difference of flat-band voltage as set by the Fermi-level of n+ and p+ doping in the control junctions.

While the invention has been particularly shown and described with reference to the preferred embodiments thereof, it will be understood by those skilled in the art that various changes in form and details may be made without departing from the spirit and scope of the invention.

What is claimed is:

1. A vertical resistor structure, comprising:
at least one shallow trench isolation (STI) structure deposited in a substrate of a first conductivity type;
a channel region of said first conductivity type formed adjacent and in contact with at least one STI structure, said channel region having a parasitic resistance;
a control junction of a second conductivity type butting against that side of said STI structure not in contact with said channel region, said control junction coupled to a voltage source;
a lightly doped drain (ldd) junction of said first conductivity type deposed on top of said channel region to form a contact with said channel region, said ldd junction coupled to a second voltage source; and
said substrate coupled to a voltage source return.

2. The structure of claim 1, wherein said control junction serves as a control for modulating said parasitic resistance through said STI structure when applying a voltage bias to said control junction.

3. The structure of claim 1, wherein said parasitic resistance is modulated by a depletion layer in said channel region formed along a side-wall of said STI structure.

4. The structure of claim 1, wherein said control junction may further surround said channel region.

5. The structure of claim 1, wherein said control junction induces a depletion region in said channel region.

6. The structure of claim 1, wherein said control junction induces an accumulation region in said channel region.

7. A vertical resistor structure, comprising:
two shallow trench isolation (STI) structures deposited in a well of a first conductivity type;
a channel region formed between said two STI structures, said channel region having a parasitic resistance;
a lightly doped drain (ldd) junction of said first conductivity type deposed on top of said channel region to form a contact with said channel region;
one or more control junctions of a second conductivity type butting against that side of each of said STI structures not in contact with said channel region, where said control junction may further surround said channel region; and
said well coupled to a voltage source return.

8. The structure of claim 7, wherein said control junctions serve as a control for modulating said parasitic resistance by applying a voltage bias to said control junctions.

9. The structure of claim 7, wherein said parasitic resistance is modulated by a depletion layer in said channel region formed along a side-wall of at least one of said STI structures.

10. The structure of claim 7, wherein said ldd junction has a thickness ranging from 20 to 100 nm (nm=nanometers).

11. The structure of claim 7, wherein the top surface of said ldd junction is flush with the top surface of said well.

12. The structure of claim 7, wherein the depth of said control junction ranges from 0.1 to 0.5 um (um=10⁻⁶ meter) where the depth of said control junction cannot exceed the depth of said shallow trench isolation structures.

13. The structure of claim 7, wherein the depth of said STI structure ranges from 0.3 to 0.5 um (um=10⁻⁶ meter).

14. The structure of claim 7, wherein said well is disposed in a substrate of said second conductivity type.

15. The structure of claim 7, wherein said substrate is coupled to a reference potential.

16. The structure of claim 7, wherein said ldd junction is coupled to a first voltage source.

17. The structure of claim 7, wherein said control junction is coupled to a second voltage source.

18. A vertical variable resistor, comprising:
two shallow trench isolation (STI) structures deposited in a well of a first conductivity type;
a channel region formed between said two STI structures, said channel region having a parasitic resistance;
a lightly doped drain (ldd) junction of said first conductivity type deposed on top of said channel region to form a contact with said channel region.
at least one control junction of a second conductivity type butting against that side of each of said STIs not in contact with said channel region, said control junction coupled to a first voltage source, said control junction inducing an STI field penetration effect in said channel region;
said ldd junction coupled to a second voltage source; and
said well coupled to a voltage source return.

19. The vertical variable resistor of claim 18, wherein said control junction serves as a control for modulating said parasitic resistance by applying a voltage bias to said control junction.

20. The vertical variable resistor of claim 18, wherein said parasitic resistance is modulated by a depletion layer in said channel region formed along at least one side-wall of said STI through said STI field penetration effect.

21. The vertical variable resistor of claim 18, wherein the doping of said channel region is separately implanted to optimize the doping concentration of said channel region.

22. The vertical variable resistor of claim 18, wherein said STI structure is made deeper by applying extra masking and etching steps, thus ranging in depth from 0.3 to 2.0 um (um=10⁻⁶ meter) but not exceeding an n-well depth.

23. The vertical variable resistor of claim 18, wherein said STI structure is made deeper by applying extra masking and etching steps, thus ranging in depth from 0.3 to 2.0 um (um=10⁻⁶ meter) but not exceeding a deep n-well depth.

24. The vertical variable resistor of claim 18, wherein said well is disposed in a substrate of said second conductivity type.

25. The vertical variable resistor of claim 24, wherein said substrate is coupled to a ground potential.

26. A structure for a vertical field effect transistor (FET), comprising:
two shallow trench isolation (STI) structures deposited in a well of a first conductivity type;
a channel region formed between said two STI structures, said channel region having a parasitic resistance;
a lightly doped drain (ldd) junction of said first conductivity type deposed on top of said channel region to form a contact with said channel region;
a base of a second conductivity type deposited on one side of each of said STI structures, said base in contact with that side of said STI structure not in contact with said channel region; and
at least one control junction of a second conductivity type butting against that side of each of said STI structures not in contact with said channel region, where each of said control junctions is in contact with one of said bases.

27. The structure for an FET of claim 26, wherein said control junction serves as a control for creating a depletion layer in said channel region by applying a voltage bias of a first polarity to said control junction.

28. The structure for an FET of claim 26, wherein said control junction serves as a control for creating an accumulation layer in said channel region when applying a voltage bias of a second polarity to said control junction.

29. The structure for an FET of claim 26, wherein said well is disposed in a substrate of said second conductivity type.

30. A vertical field effect transistor (FET), comprising:
two shallow trench isolation (STI) structures deposited in a well of a first conductivity type;
a channel region formed between said two STI structures, said channel region having a vertical parasitic resistance;
a lightly doped drain (ldd) junction of said first conductivity type deposed on top of said channel region to form a contact with said channel region;
a base of a second conductivity type deposited on one side of each of said STI structures, said base in contact with that side of said STI structure not in contact with said channel region; and
one or more control junctions of said second conductivity type butting against that side of each of said STI structures not in contact with said channel region, where each of said control junctions is in contact with said base, where the field penetration effect of said control junctions, when biased, modulates said vertical parasitic resistance of said channel region.

31. The vertical FET of claim 30, wherein said well is disposed in a substrate of said second conductivity type.

32. The vertical FET of claim 30, wherein, when said second conductivity is a p+ type, said control junctions are biased with a positive voltage source relative to a reference potential to cause said channel region to have a depletion layer.

33. The vertical FET of claim 32, wherein said vertical FET is in the “OFF” mode when said channel region has a depletion layer.

34. The vertical FET of claim 30, wherein, when said second conductivity is a p+ type, said control junctions are biased with a negative voltage source relative to a reference potential to cause said channel region to have a hole accumulation layer.

35. The vertical FET of claim 34, wherein said vertical FET is in the “ON” mode when said channel region has a hole accumulation layer.

36. The vertical FET of claim 30, wherein, when said second conductivity is a n+ type, said control junctions are biased with a negative voltage source relative to a reference potential to cause said channel region to have a depletion layer.

37. The vertical FET of claim 36, wherein said vertical FET is in the “OFF” mode when said channel region has a depletion layer.

38. The vertical FET of claim 36, wherein, when said second conductivity is a n+ type, said control junctions are biased with a positive voltage source relative to a reference potential to cause said channel region to have an electron accumulation layer.

39. The vertical FET of claim 38, wherein said vertical FET is in the “ON” mode when said channel region has an electron accumulation layer.

40. The vertical FET of claim 30, wherein said control junctions surround said channel region.

41. A band-gap reference circuit using vertical field effect transistors (FETs), comprising:
three shallow trench isolation (STI) structures deposited in a well of a first conductivity type;
first and a second channel regions formed between said three STI structures, such that there is one inner and two outer STIs, where said first and second channel region together with said inner and an outer STIs comprise a first and a second vertical FET, respectively, said channel regions having a parasitic resistance;
a lightly doped drain (ldd) junction of said first conductivity type deposed on top of each of said channel regions to form contacts with said channel regions;
a control junction of first and second conductivity type each, butting against said outer STIs, respectively, where said first and said second control junction function as gates for said first and said second vertical FET, respectively; and
a base of a second conductivity type buried in said well, said well in contact with said control junction and the lower part of one of said outer STIs.

42. The band-gap reference circuit of claim 41, wherein said first control junction is coupled to a reference potential.

43. The band-gap reference circuit of claim 41, wherein a first input of an amplifier and a first current source are coupled to said first channel region.

44. The band-gap reference circuit of claim 43, wherein a second input of said amplifier and a second current source are coupled to said second channel region.

45. The band-gap reference circuit of claim 44, wherein the output of said amplifier is coupled to said second control junction.

46. The band-gap reference circuit of claim 41, wherein parasitic resistances of said well serve as load resistors for said first and second vertical FET.

47. A band-gap reference circuit using vertical n-field effect transistors (n-FETs), comprising:
three shallow trench isolation (STI) structures deposited in an n-well of a first conductivity type;
first and a second channel regions formed between said three STI structures, such that there is one inner and two outer STIs, where said first and second channel region together with said inner and an outer STIs constitute a first and a second vertical n-FET, respectively, said channel regions having a parasitic resistance;
a p-lightly doped drain (pldd) junction deposited on top of each of said channel regions to form contacts with said channel regions;
an n+ control junction butting against one of said outer STIs, where said n+ control junction functions as a gate for said first vertical n-FET;
a p+ control junction butting against the other of said outer STIs, where said p+ control junction functions as a gate for said second vertical n-FET; and
a p-base buried in said n-well, said p-base in contact with said n+ control junction and the lower part of said one outer STI.

48. The band-gap reference circuit of claim 47, wherein said n-well is deposited on a p-substrate.

49. The band-gap reference circuit of claim 48, where said p-substrate is coupled to a power supply more negative than a reference supply.

50. The band-gap reference circuit of claim 47, wherein two n-FETs operating in their linear region are formed by coupling said n-well and said pldd to a power supply more positive and more negative than a reference supply, respectively.

51. The band-gap reference circuit of claim 47, wherein two n-FETs operating in their saturation region are formed by coupling said n-well and said pldd to a power supply more negative and more positive than a reference supply, respectively.

52. A band-gap reference circuit using vertical p-field effect transistors (p-FETs), comprising:
three shallow trench isolation (STI) structures deposited in a p-well.
a first and a second channel regions formed between said three STI structures, such that there is one inner and two outer STIs, where said first and second channel region together with said inner and an outer STIs constitute a first and a second vertical p-FET, respectively, said channel regions having a parasitic resistance;
an n-lightly doped drain (nldd) junction deposited on top of each of said channel regions to form contacts with said channel regions;
a p+ control junction butting against one of said outer STIs, where said p+ control junction functions as a gate for said first vertical p-FET;
an n+ control junction butting against the other of said outer STIs, where said n+ control junction functions as a gate for said second vertical p-FET; and
an n-base buried in said p-well, said n-base in contact with said p+ control junction and the lower part of said one outer STI.

53. The band-gap reference circuit of claim 52, wherein said p-well is deposited on an n-well.

54. The band-gap reference circuit of claim 53, where said n-well is coupled to a power supply more positive than a reference supply.

55. The band-gap reference circuit of claim 52, wherein two p-FETs operating in their linear region are formed by coupling said p-well and said nldd to a power supply more negative and more positive than a reference supply, respectively

56. The band-gap reference circuit of claim 52, wherein two p-FETs operating in their saturation region are formed by coupling said p-well and said nldd to a power supply more positive and more negative than a reference supply, respectively.

57. A method of fabricating vertical resistors, comprising the steps of:
a) STI isolation formation:
Cleaning, pad-oxide growing, depositing Si3N4;
AA masking, trench etching, cleaning;
Deep trench masking, deep trench etching;
Liner oxidation, HDP CVD oxide depositing, RTA densify;
Oxide CM polishing, Si3N4 removing;
b) Transistor formation:
p-well (1) masking, implanting;
p-well (2) masking, implanting;
n-well (1) masking, implanting;
n-well (2) masking, implanting;
resistor (p-type) area masking and implanting;
resistor (n-type) area masking and implanting;
c) Gate formation:
1st gate-oxidation;
Dual gate-oxide masking, wet oxide dipping;
Cleaning, 2nd gate-oxidation, depositing undoped Poly;
gate masking, poly etching, cleaning, poly-oxidation;
d) Transistor formation:
nldd-1 masking, implanting;
pldd-1 masking, implanting;
pldd-2 masking, implanting;
nldd-2 masking, implanting;
Liner-oxidation, depositing gate spacer (SiN, Teox);
Gate spacer oxide/SiN etching, cleaning;
n+ S/D and p+ S/D, masking, implanting;
deep n+ masking and implanting;
deep p+ masking and implanting;
e) Salicide and contact:
Co depositing, TiN depositing, RT Annealing-1, Co stripping, RT Annealing-2;
SiN depositing, PSG depositing, ILD CMP polishing;
Contact masking, contact oxide etching;
W-CVD depositing, W-CMP polishing; and
f) Continuing with BEOL metal interconnecting.

58. The method of fabricating vertical resistors of claim 57, wherein the step in d) of deep n+ masking and implanting further includes implanting of a p-base.

59. The method of fabricating vertical resistors of claim 57, wherein the step in d) of deep p+ masking and implanting further includes implanting of an n-base.
